(19) United States
(12) Patent Application Publication
(10) Pub. No.: US 2025/0246257 A1
(43) Pub. Date: Jul. 31, 2025

(54) WORD LINE BRIDGE DETECTOR OF SEMICONDUCTOR MEMORY DEVICE AND METHOD FOR DETECTING WORD LINE BRIDGE THEREOF

(71) Applicant: SAMSUNG ELECTRONICS CO., LTD., Suwon-si (KR)

(72) Inventors: Jungkwan Kim, Suwon-si (KR); Sang-Won Park, Suwon-si (KR); Il Han Park, Suwon-si (KR)

(21) Appl. No.: 18/814,231

(22) Filed: Aug. 23, 2024

(30) Foreign Application Priority Data
Jan. 29, 2024 (KR) 10-2024-0013478

(51) Int. Cl. G11C 29/44; G11C 29/12; G11C 29/18

(52) U.S. Cl. CPC G11C 29/44; G11C 29/18; G11C 2029/1202; G11C 2029/1802

(57) ABSTRACT

A memory device includes a memory cell array connected to a first word line and a second word line; an address decoder configured to select the first word line or the second word line; and a word line bridge detector configured to detect whether a word line bridge exists between the first and second word lines. The word line bridge detector precharges the first word line by connecting it to a detection node during a word line precharge operation, changes a selected word line from the first word line to the second word line. And the word line bridge detector connects the second word line to the detection node during a word line develope operation, and detects whether a word line bridge exists between the first and second word lines by detecting a change in the voltage level of the detection node.

### CROSS-REFERENCE TO RELATED APPLICATION(S)

This application claims priority to Korean Patent Application No. 10-2024-0013478 filed in the Korean Intellectual Property Office on Jan. 29, 2024, the disclosure of which is incorporated by reference herein in its entirety.

### BACKGROUND

Semiconductor memories may be classified as a volatile memory or a non-volatile memory, for example. Typically, the volatile memories (e.g., a dynamic random access memory (DRAM) or a static random access memory (SRAM)) may exhibit faster read and/or write speeds when compared to the non-volatile memory. However, data stored in the volatile memory may disappear when a power applied to the volatile memory is turned off. In contrast, the non-volatile memory may retain the data even when the power is turned off.

A representative example of the non-volatile memory may be a flash memory. The flash memory may store multi-bit data of two or more bits in one memory cell. The flash memory may have at least one erase state and a plurality of program (e.g., writing) states depending on threshold voltage distributions.

The flash memory may include a plurality of memory blocks. Each memory block may be connected to a plurality of word lines. Bridges that cause defects may occur between word lines in flash memory. If a bridge occurs between word lines, a defect may occur because current flows through the bridge.

Conventionally, leakage is measured in one word line to detect defects due to word line bridges. However, since the conventional word line bridge detection method measures one word line, defect detection may not be accurate.

### SUMMARY

In general, in some aspects, the present disclosure is directed to detecting whether a bridge exists between two word lines by changing a selected word line among the two word lines.

According to some implementations, the present disclosure is directed to a memory device comprising a memory cell array connected to a first word line and a second word line; an address decoder configured to select the first word line or the second word line; and a word line bridge detector configured to detect whether a word line bridge exists between the first and second word lines. The word line bridge detector precharges the first word line by connecting it to a detection node during a word line precharge operation, changes a selected word line from the first word line to the second word line. And the word line bridge detector connects the second word line to the detection node during a word line develope operation, and detects whether a word line bridge exists between the first and second word lines by detecting a change in the voltage level of the detection node.

According to some implementations, the present disclosure is directed to a word line bridge detector of a memory device that comprises a word line selector configured to select a first word line or a second word line during a word line bridge detection operation; a voltage switch configured to provide a precharge voltage to the first word line during a word line precharge operation and detect the voltage level of a detection node during a word line develope operation; a comparator configured to compare the voltage level of the detection node and a reference voltage and generate a leakage detection signal as a result of the comparison; and a leakage monitor configured to receive the leakage detection signal from the comparator and generate a leakage monitor signal. The word line selector precharges the first word line by connecting it to a detection node during a word line precharge operation, changes a selected word line from the first word line to the second word line. And the word line selector connects the second word line to the detection node during a word line develope operation, and detects whether a word line bridge exists between the first and second word lines by detecting a change in the voltage level of the detection node.

According to some implementations, the present disclosure is directed to a word line bridge detection method of a memory device that includes a memory cell array connected to a first word line and a second word line; an address decoder configured to select the first word line or the second word line; and a word line bridge detector configured to detect whether a word line bridge exists between the first and second word lines, the word line bridge detection method comprises: precharging the first word line by connecting it to a detection node during a word line precharge operation; changing a selected word line from the first word line to the second word line; connecting the second word line to the detection node during a word line develope operation; and detecting whether a word line bridge exists between the first and second word lines through a change in the voltage level of the detection node.

### BRIEF DESCRIPTION OF THE DRAWINGS

Example implementations will be more clearly understood from the following detailed description, taken in conjunctions with the accompanying drawings.

FIG. 1 is a block diagram illustrating an example of a storage device according to some implementations.

FIG. 2 is a block diagram illustrating as an example of the memory device illustrated in FIG. 1 according to some implementations.

FIG. 3 is a circuit diagram illustrating an example of a memory block BLK1 of the memory cell array illustrated in FIG. 2 according to some implementations.

FIG. 4 is a circuit diagram illustrating examples of cell strings selected by the first string selection line SSL1 from among the cell strings of the memory block BLK1 illustrated in FIG. 3 according to some implementations.

FIG. 5 is a circuit diagram illustrating an example of a word line bridge detector shown in FIG. 2 according to some implementations.

FIGS. 6 to 8 are circuit diagrams illustrating examples in which there are no bridges between the WLa word line and the WLb word line according to some implementations.

FIGS. 9 to 11 illustrate an example of WL bridges between the WLa word line and the WLb word line according to some implementations.

FIG. 12 is a flowchart illustrating an example of a method of operating the word line bridge detector shown in FIG. 5 according to some implementations.

FIG. 13 is a diagram illustrating an example of a flash memory having a multi-stack structure according to some implementations.

FIG. 14 is a block diagram illustrating an example in which a storage device is implemented with a solid state drive (SSD) according to some implementations.

### DETAILED DESCRIPTION

Hereinafter, example implementations will be explained in detail with reference to the accompanying drawings.

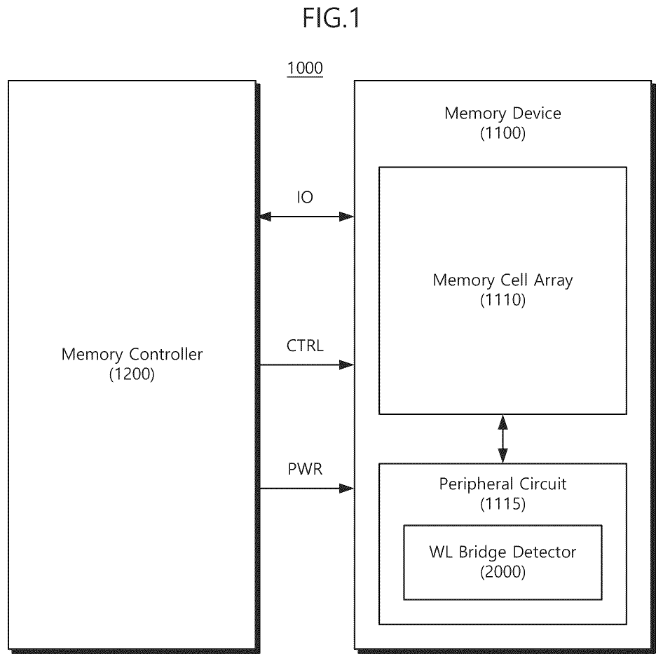

FIG. 1 is a block diagram illustrating an example of a storage device according to some implementations. The storage device 1000 may be a flash storage device based on a flash memory. For example, the storage device 1000 may be implemented as a solid-state drive (SSD), a universal flash storage (UFS), a memory card, or the like.

In FIG. 1, the storage device 1000 may include a memory device 1100 and a memory controller 1200. The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure. The memory cell array 1110 may include a plurality of memory cells. Multi-bit data may be stored in each memory cell.

The memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure.

The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. In some implementations, or additionally, the peripheral circuit 1115 may read data stored in the memory cell array 1110 and provide the read data to the memory controller 1200.

The peripheral circuit 1115 may include a word line bridge detector 2000. The word line bridge detector 2000 may perform a word line bridge detection operation in a test mode of the memory device 1100. The memory device 1100 may perform the test mode at the manufacturing stage before being sold as a product, and may operate in a user mode after being sold as a product. The memory device 1100 may detect defects such as word line bridges in the test mode.

Additionally, the memory device 1100 may perform a word line bridge detection operation even in the user mode. Even after the memory device 1100 is sold as a product and is in use, defects due to word line bridges may occur in the memory device 1100. The memory device 1100 may detect defective word lines through a word line bridge detection operation.

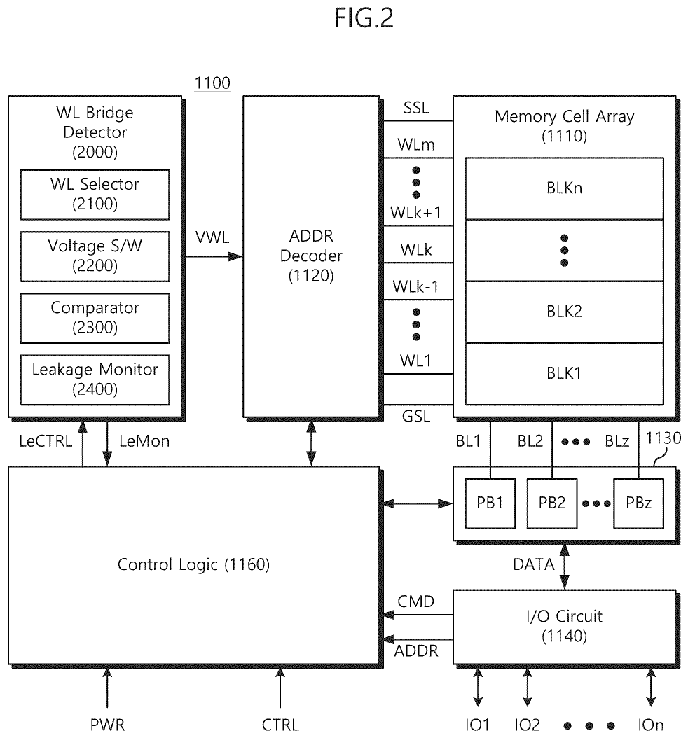

FIG. 2 is a block diagram illustrating as an example of the memory device illustrated in FIG. 1 according to some implementations. In FIG. 2, the memory device 1100 may include the memory cell array 1110 and the peripheral circuit 1115 (see FIG. 1). The peripheral circuit 1115 may include an address decoder 1120, a page buffer circuit 1130, a data input/output circuit 1140, a control logic 1160, and a word line bridge detector 2000.

The memory cell array 1110 may include a plurality of memory blocks BLK1 to BLKn. Each memory block may include a plurality of pages. Each page may include a plurality of memory cells. Each memory cell may store multi-bit data (e.g., two or more bits). Each memory block may correspond to an erase unit, and each page may correspond to a read and/or write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selected word line sWL and the remaining word lines (WL1 to WLk−1, WLk+1 to WLm) are unselected word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selected word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to IOn. The input/output circuit 1140 may receive program data from the memory controller 1200 during a program operation. Also, the input/output circuit 1140 may provide data read from the memory cell array 1110 to the memory controller 1200 during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The word line bridge detector 2000 may include a word line selector 2100, a voltage switch 2200, a comparator 2300, and a leakage monitor 2400. The word line bridge detector 2000 may receive a leakage control signal (LeCTRL) from the control logic 1160 and perform a word line bridge detection operation. The word line bridge detector 2000 may provide a leakage monitor signal (LeMon) to the control logic 1160 as a detection result.

The word line selector 2100 may select one of two word lines during a word line bridge detection operation. The voltage switch 2200 may provide a precharge voltage to a selected word line during a word line precharge operation and detect the voltage level of a detection node during a word line develope operation. The comparator 2300 may compare the voltage level of the detection node and the reference voltage and generate a leakage detection signal as a result of the comparison. The leakage monitor 2400 may receive a leakage detection signal from the comparator 2300 and generate a leakage monitor signal (LeMon).

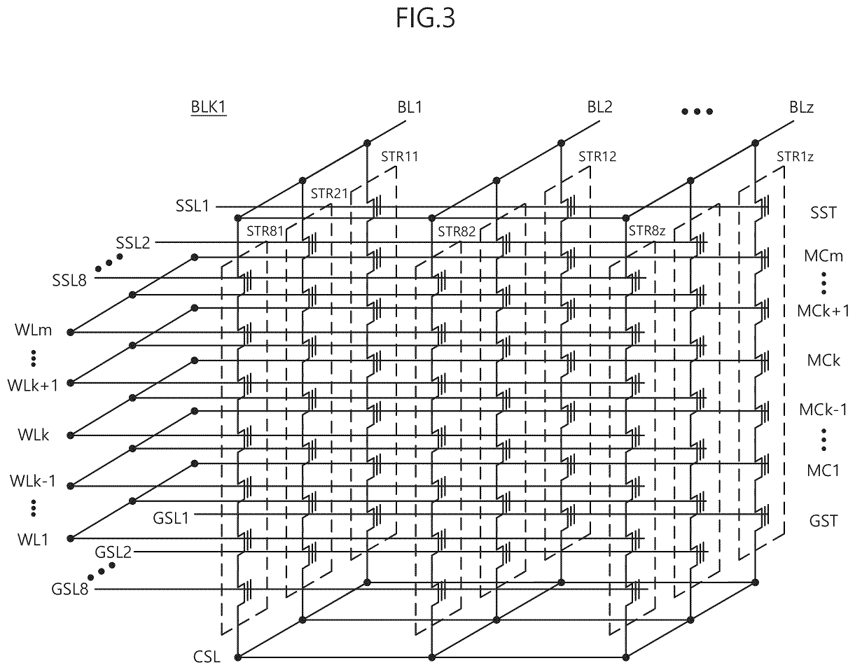

FIG. 3 is a circuit diagram illustrating an example of a memory block BLK1 of the memory cell array illustrated in FIG. 2 according to some implementations. In FIG. 3, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLZ.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m-1)-th memory cells MC2 to MCm-1 that are placed at the same heights from the substrate may be respectively connected with the second to (m-1)-th word lines WL2 to WLm-1, respectively.

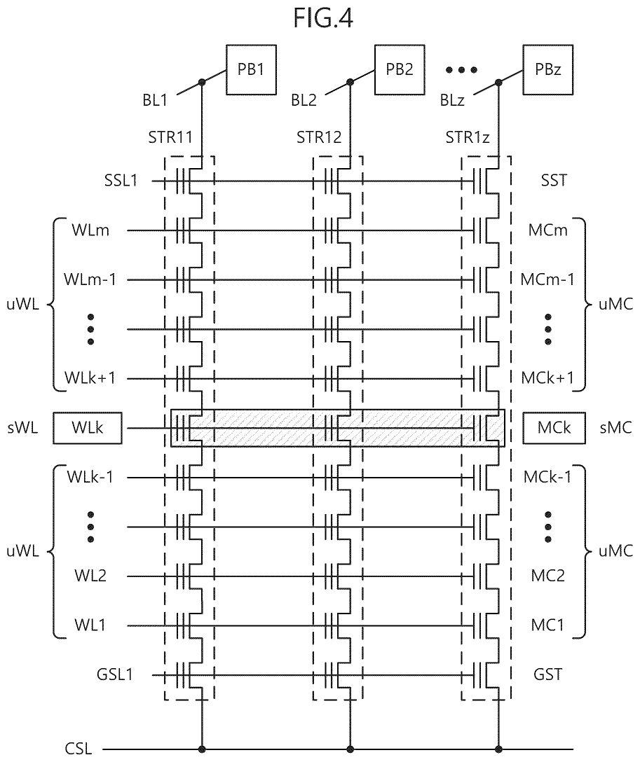

FIG. 4 is a circuit diagram illustrating examples of cell strings selected by the first string selection line SSL1 from among the cell strings of the memory block BLK1 illustrated in FIG. 3 according to some implementations. The 11th to 1z cell strings STR11 to STR1z may be selected by the first string selection line SSL1. The eleventh to 1z cell strings STR11 to STR 1z may be connected to the first to z-th bit lines BL1 to BLz, respectively. The first to z-th page buffers PB1 to PBz may be connected to the first to z-th bit lines BL1 to BLz, respectively.

The eleventh cell string STR11 may be connected to the first bit line BL1 and the common source line CSL. The eleventh cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The twelfth cell string STR12 may be connected to the second bit line BL2 and the common source line CSL. The 1z cell string STR1z may be connected to the z-th bit line BLz and the common source line CSL.

The first word line WL1 and the m-th word line WLm may be edge word lines (edge WL). The second word line WL2 and the (m-1)-th word line WLm-1 may be edge-adjacent word lines. The k-th word line WLk may be a selected word line sWL. The (k-1)-th word line WLk-1 and the (k+1)-th word line WLk+1 may be adjacent word lines adjacent to the selected word line. If the k-th word line WLk is the selected word line sWL, the remaining word lines WL1 to WLk-1 and WLk+1 to WLm may be unselected word lines uWL.

The first memory cells MC1 and the m-th memory cells MCm may be edge memory cells. The second memory cells MC2 and the (m-1)-th memory cells MCm-1 may be edge-adjacent memory cells. The k-th memory cells MCk may be selected memory cells sMC. The (k-1)-th memory cells MCk-1 and the (k+1)-th memory cells MCk+1 may be memory cells adjacent to the selected memory cells (adjacent MC). If the k-th memory cells MCK are selected memory cells sMC, the remaining memory cells MC1 to MCk-1 and MCk+1 to MCm may be unselected memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

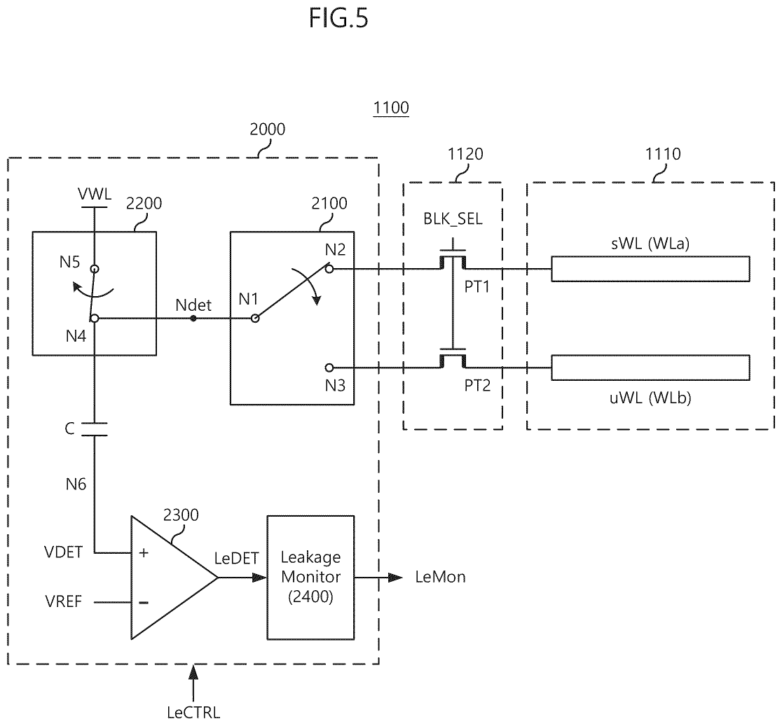

FIG. 5 is a circuit diagram illustrating an example of a word line bridge detector shown in FIG. 2 according to some implementations. In FIG. 5, the memory device 1100 may include a memory cell array 1110, an address decoder 1120, and a word line bridge detector 2000.

The memory cell array 1110 may include WLa and WLb word lines. The WLa word line may be a selected word line sWL and WLb may be an unselected word line uWL. The WLa word line and the WLb word line may be adjacent word lines or may be non-adjacent word lines. The WLa word line and the WLb word line may be located within the same memory block.

The address decoder 1120 may select a memory block and/or a word line. The address decoder 1120 may receive a block address and select one memory block. An operation of selecting one memory block may be performed by providing a block selection signal BLK_SEL to the gates of the pass transistors.

For example, the block selection signal BLK_SEL may be provided to the gates of the first and second pass transistors PT1 and PT2. The first pass transistor PT1 may be connected to the WLa word line, and the second pass transistor PT2 may be connected to the WLb word line. The first and second pass transistors PT1 and PT2 may be durable to high voltages such as program voltage or erase voltage.

The address decoder 1120 may receive a row address and select one word line. For example, the address decoder 1120 may set the WLa word line as the selected word line sWL and the WLb word line as the unselected word line uWL. The address decoder 1120 may change the selected word line sWL from the WLa word line to the WLb word line by changing the row address.

The word line bridge detector 2000 may include a word line selector 2100, a voltage switch 2200, a comparator 2300, and a leakage monitor 2400. The word line bridge detector 2000 may receive a leakage control signal (LeCTRL) from the control logic (see FIG. 2, 1160) and output a leakage monitor signal (LeMon).

The word line selector 2100 may receive the leakage control signal (LeCTRL) and select the WLa word line or the WLb word line. For example, the word line selector 2100 may include first to third nodes N1 to N3. The first node N1 may be connected to the detection node Ndet, the second node N2 may be connected to the WLa word line, and the third node N3 may be connected to the WLb word line.

The word line selector 2100 may connect the first node N1 to the second node N2 when selecting the WLa word line, and may connect the first node N1 to the third node N3 when selecting the WLb word line. The word line selector 2100 may change the selected word line by connecting the second node N2 or the third node N3 to the first node N1.

The voltage switch 2200 may receive a leakage control signal LeCTRL and provide a word line voltage VWL to the detection node Ndet. For example, the voltage switch 2200 may include fourth and fifth nodes N4 and N5. The fourth node N4 may be connected to the detection node Ndet, and the fifth node N5 may be connected to the power terminal.

When precharging the word line, the voltage switch 2200 may provide a word line voltage VWL at a predetermined level to the selected word line and may charge a capacitor C connected between the fourth node N4 and the sixth node N6. The voltage switch 2200 may provide the level of the detection node Ndet to the comparator 2300 through the capacitor C during word line develope operation. The voltage switch 2200 may connect the fourth node N4 to the fifth node N5 during word line precharge, and may separate the fourth node N4 from the fifth node N5 during word line develop operation.

The comparator 2300 may receive a detection voltage VDET and a reference voltage VREF, and may generate a leakage detection signal LeDET. The detection voltage VDET may be provided to the (+) terminal of the comparator 2300, and the reference voltage VREF may be provided to the (−) terminal of the comparator 2300. The detection voltage VDET may be the voltage level of the detection node Ndet. In some implementations, the detection voltage VDET may change in conjunction with the voltage level of the detection node Ndet.

The comparator 2300 may compare the detection voltage VDET and the reference voltage VREF and generate a leakage detection signal LeDET according to the comparison result. For example, if the detection voltage VDET continues to be higher than the reference voltage VREF, the comparator 2300 may generate a signal indicating that leakage has occurred. If the detection voltage VDET is lower than the reference voltage VREF, the comparator 2300 may generate a signal indicating that leakage does not occur.

The leakage monitor 2400 may receive a leakage detection signal LeDET and generate a leakage monitor signal LeMon. The leakage monitor signal LeMon may be provided to the control logic 1160. The leakage monitor 2400 may determine whether there is a bridge or leakage between the WLa word line and the WLb word line through the leakage detection signal LeDET.

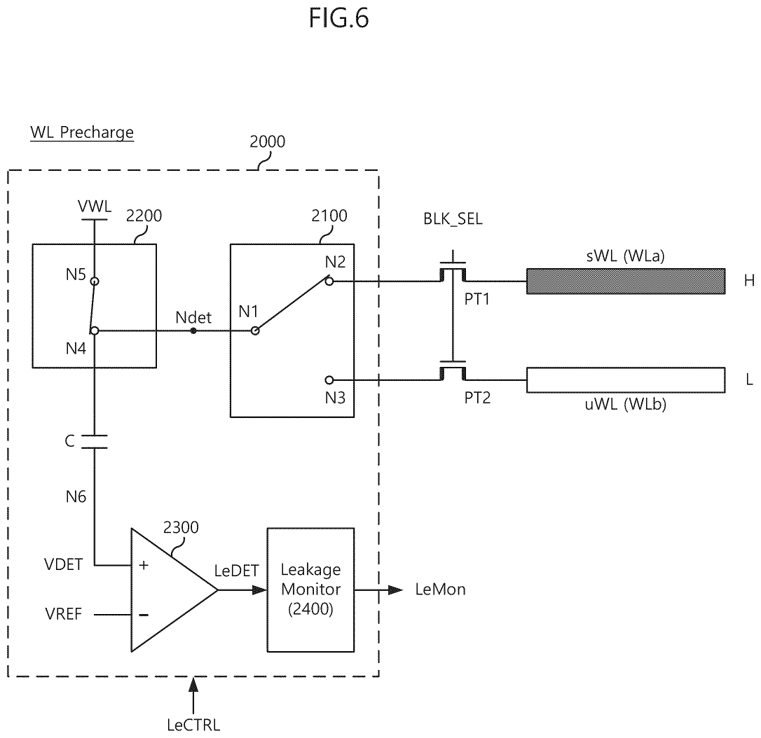

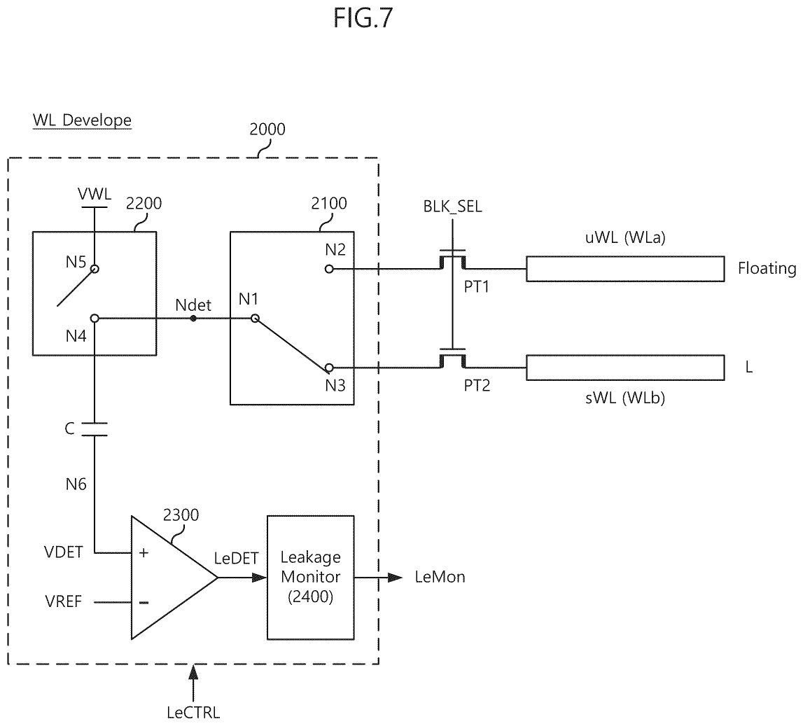

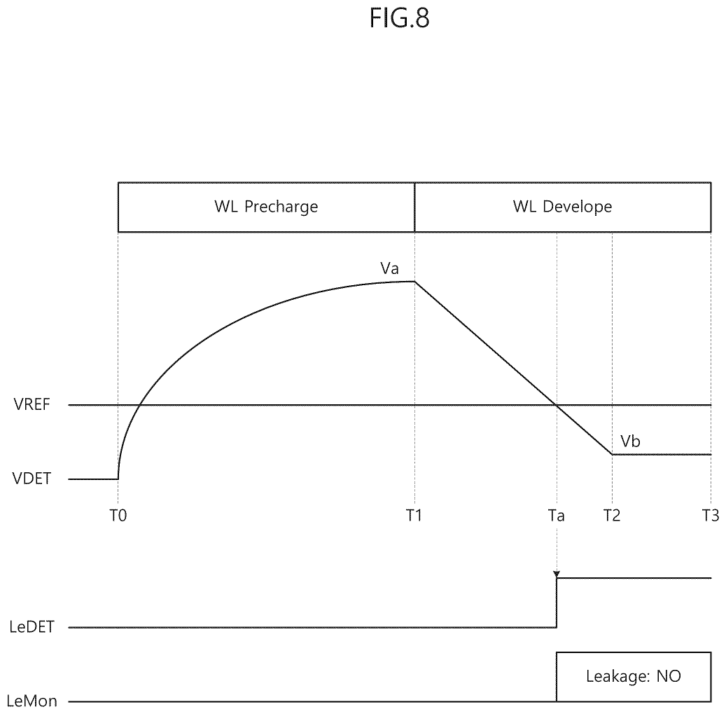

FIGS. 6 to 8 are circuit diagrams illustrating examples in which there are no bridges between the WLa word line and the WLb word line according to some implementations. FIG. 6 illustrates an example of a word line precharge operation. FIG. 7 illustrates an example of a word line develop operation. FIG. 8 is an example of a timing diagram of the word line precharge operation and the word line develop operation.

In FIG. 6, during a word line precharge operation, the word line selector 2100 may select the WLa word line. The first node N1 of the word line selector 2100 may be connected to the second node N2. The voltage switch 2200 may provide the word line voltage VWL to the detection node Ndet. The fourth node N4 of the voltage switch 2200 may be connected to the fifth node N5.

During the word line precharge operation, the WLa word line, which is the selected word line sWL, may be precharged to the high level (H). And the WLb word line, which is the unselected word line uWL, may be precharged to the low level (L).

In FIG. 7, during a word line develop operation, the word line selector 2100 may select the WLb word line. The first node N1 of the word line selector 2100 may be connected to the third node N3. The fourth node N4 of the voltage switch 2200 may be separated from the fifth node N5. The detection node Ndet may be connected to the sixth node N6 through the capacitor C.

During a word line develop operation, the selected word line sWL may be changed from the WLa word line to the WLb word line. The WLa word line, which is an unselected word line uWL, may be in a floating state. And the WLb word line, which is a selected word line sWL, may be at a low level (L). The voltage level of the detection node Ndet may be lowered by charge sharing with the WLb word line.

The comparator 2300 may compare the detection voltage VDET and the reference voltage VREF and generate a leakage detection signal LeDET according to the comparison result. When the detection voltage VDET becomes lower than the reference voltage VREF due to charge sharing, the comparator 2300 may generate a leakage detection signal LeDET indicating that leakage does not occur.

The leakage monitor 2400 may receive a leakage detection signal LeDET and generate a leakage monitor signal LeMon. The leakage monitor 2400 may use the leakage detection signal LeDET to determine that there is no bridge and no leakage between the WLa word line and the WLb word line.

In FIG. 8, during the word line precharge period (T0 to T1), the detection voltage VDET may rise to the Va level. The WLa word line may receive the word line voltage VWL and be precharged to a high level (H). At this time, the detection voltage VDET may rise to the Va level.

During the word line develop period (T1 to T3), the detection voltage VDET may fall to the Vb level. The WLa word line may be in a floating state. And the WLb word line may perform charge sharing with the detection node Ndet. Due to charge sharing, the detection voltage VDET may fall to the Vb level until T2.

The detection voltage VDET may be lower than the reference voltage VREF at Ta. When the detection voltage VDET becomes lower than the reference voltage VREF, the leakage detection signal LeDET may change from a low level to a high level. The leakage monitor 2400 may use the leakage detection signal LeDET to generate a leakage monitor signal LeMon indicating that there is no leakage between the WLa word line and the WLb word line.

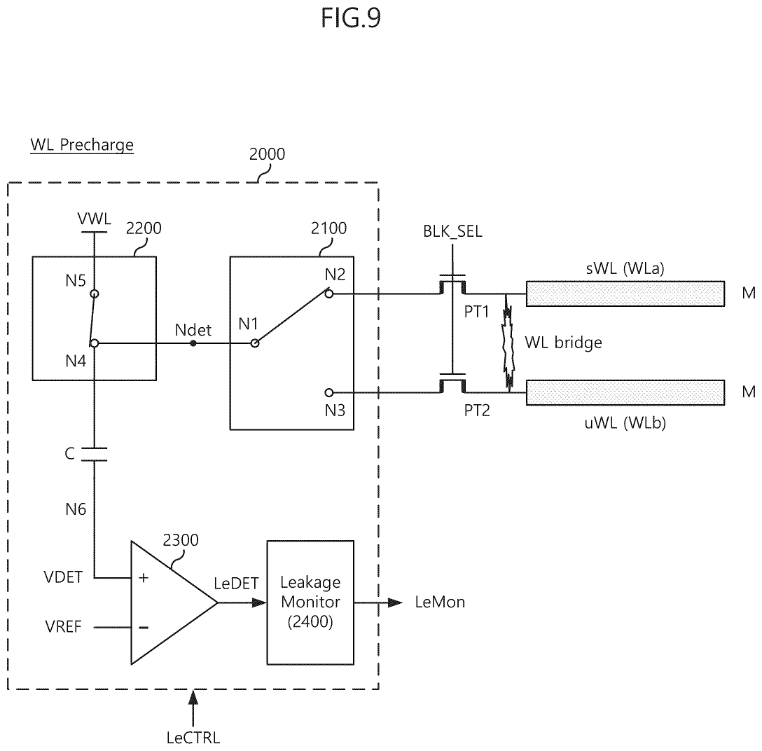

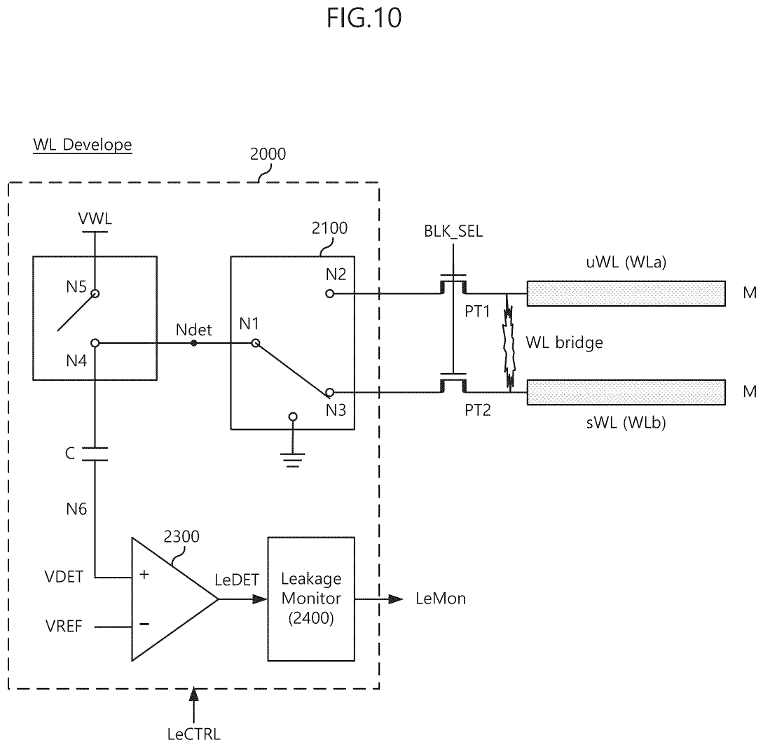

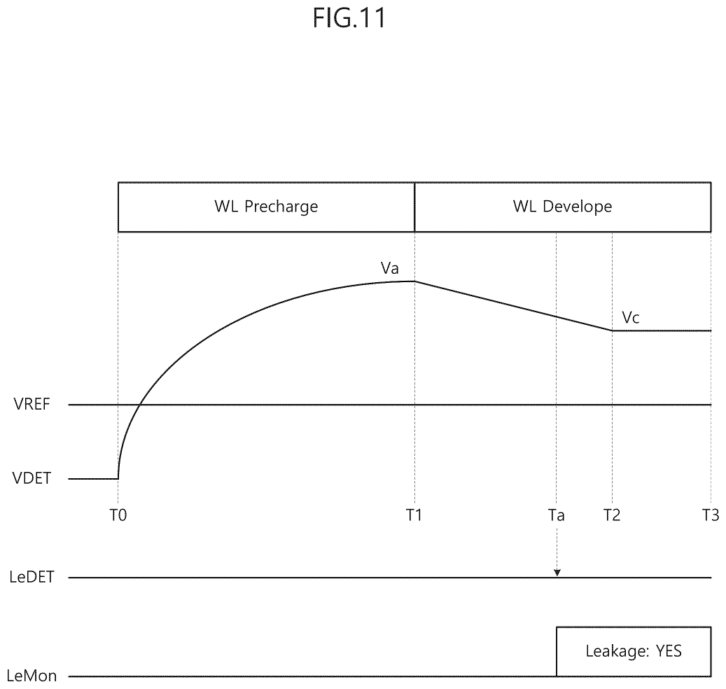

FIGS. 9 to 11 illustrate an example of WL bridges between the WLa word line and the WLb word line according to some implementations. FIG. 9 is a circuit diagram illustrating an example of a word line precharge operation. FIG. 10 is a circuit diagram illustrating an example of a word line develop operation. FIG. 11 is an example of a timing diagram of the word line precharge operation and the word line develop operation.

In FIG. 9, a word line bridge may occur between the WLa word line and the WLb word line. During a word line precharge operation, the word line selector 2100 may select the WLa word line. During the word line precharge operation, the WLa word line, which is the selected word line sWL, and the WLb word line, which is the unselected word line uWL, may be at a middle level (M) due to the word line bridge. Here, the middle level (M) may be any level between the high level (H) and the low level (L).

In FIG. 10, during a word line develop operation, the word line selector 2100 may select the WLb word line. During a word line develop operation, the selected word line sWL may be changed from the WLa word line to the WLb word line. The WLa word line, which is an unselected word line uWL, and the WLb word line, which is a selected word line sWL, may be at a middle level (M). The voltage level of the detection node Ndet may be lowered by charge sharing with the WLa word line and the WLb word line.

The comparator 2300 may compare the detection voltage VDET and the reference voltage VREF and generate a leakage detection signal LeDET according to the comparison result. If the detection voltage VDET remains higher than the reference voltage VREF, the comparator 2300 may generate a leakage detection signal LeDET indicating that leakage has occurred.

The leakage monitor 2400 may receive a leakage detection signal LeDET and generate a leakage monitor signal LeMon. The leakage monitor 2400 may use the leakage detection signal LeDET to determine that there is a bridge and/or leakage between the WLa word line and the WLb word line.

In FIG. 11, during the word line precharge period (T0 to T1), the detection voltage VDET may rise to the Va level. During the word line precharge operation, the WLa word line may be precharged to a high level (H). However, due to the word line bridge, the WLa word line and WLb word line may receive the word line voltage VWL and be precharged to the middle level (M). At this time, the detection voltage VDET may rise to the Va level.

During the word line develope period (T1 to T3), the detection voltage VDET may fall to the Vc level. During word line develop operation, the WLa word line and WLb may perform charge sharing with the detection node Ndet due to the word line bridge. Due to charge sharing, the detection voltage VDET may fall to the Vc level until T2.

The detection voltage VDET may remain higher than the reference voltage VREF even after Ta. When the detection voltage VDET continues to be higher than the reference voltage VREF, the leakage detection signal LeDET may maintain a low level. The leakage monitor 2400 may use the leakage detection signal LeDET to generate a leakage monitor signal LeMon indicating that there is leakage between the WLa word line and the WLb word line.

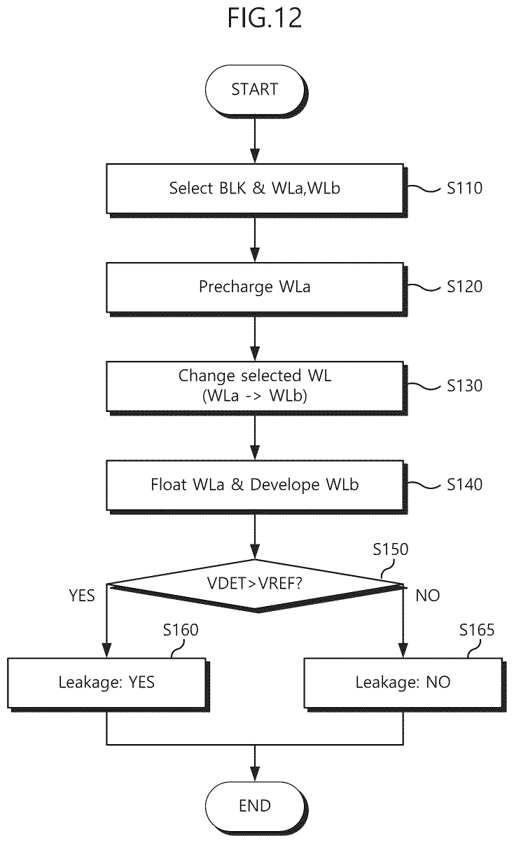

FIG. 12 is a flowchart illustrating an example of a method of operating the word line bridge detector shown in FIG. 5 according to some implementations. With reference to FIGS. 5 and 12, the example of a method of operating the word line bridge detector will be described.

In operation S110, the word line bridge detector 2000 may select a memory block and word line. For example, the word line bridge detector 2000 may select the first memory block (BLK1, see FIG. 2) and word lines to be detected for word line bridge. The word lines for word line bridge detection may be the WLa word line and the WLb word line. The WLa word line and WLb word line may be adjacent. Additionally, the WLa word line and the WLb word line may not be adjacent.

In operation S120, the word line bridge detector 2000 may perform a word line precharge operation. The word line bridge detector 2000 may precharge the WLa word line to a high level (H). At this time, the WLb word line may be low level (L). The detection node Ndet may be at a high level (H) because it is connected to the WLa word line.

In operation S130, the word line bridge detector 2000 may change the selected word line. For example, the word line bridge detector 2000 may change the selected word line sWL from the WLa word line to the WLb word line. The word line bridge detector 2000 may not provide the word line voltage VWL after changing the selected word line.

In operation S140, the word line bridge detector 2000 may perform a word line develope operation. The word line bridge detector 2000 may place the WLa word line in a floating state and connect the WLb word line to the detection node Ndet. The detection node Ndet may share charge with the WLb word line. The detection voltage VDET may be lowered by charge sharing.

In operation S150, the word line bridge detector 2000 may compare the detection voltage VDET and the reference voltage VREF. The word line bridge detector 2000 may determine whether the detection voltage VDET is higher than the reference voltage VREF while performing a word line develope operation. If the detection voltage VDET is higher than the reference voltage VREF, operation S160 may be performed. If it is lower than the reference voltage VREF, operation S165 may be performed.

In operation S160, if the detection voltage VDET continues to remain higher than the reference voltage VREF, the word line bridge detector 2000 may determine that there is a word line bridge between the WLa word line and the WLb word line. The word line bridge detector 2000 may output a leakage monitor signal LeMon indicating that there is a bridge or leakage.

In operation S165, if the detection voltage VDET is lower than the reference voltage VREF, the word line bridge detector 2000 may determine that there is no word line bridge between the WLa word line and the WLb word line. The word line bridge detector 2000 may output a leakage monitor signal LeMon indicating that there is no bridge or leakage.

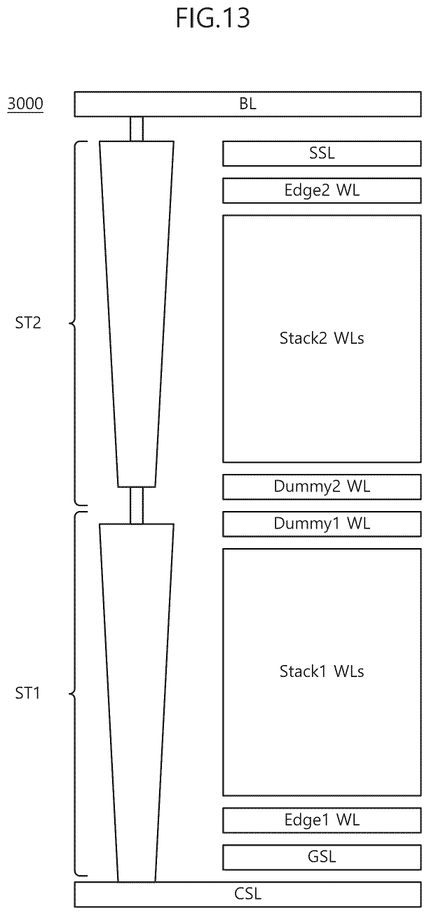

FIG. 13 is a diagram illustrating an example of a flash memory having a multi-stack structure according to some implementations. In FIG. 13, the flash memory 3000 may have a first stack ST1 and a second stack ST2. The first stack ST1 may be located at the bottom, and the second stack ST2 may be located at the top.

A pillar of the flash memory 3000 may be formed by bonding the first and second stacks ST1 and ST2. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

In some implementations, the word line bridge detector 2000 may detect between the first edge word line (Edge1 WL) and the first stack word lines (Stack1 WLs), the second stack word lines (Stack2 WLs) and the second stack word lines (Stack2 WLs). The word line bridge detector 2000 may perform a word line bridge detection operation between the first stack word lines (Stack1WLs) and the first dummy word line (Dummy1 WL). The word line bridge detector 2000 may perform a word line bridge detection operation between the second stack word lines (Stack2 WLs) and the second dummy word line (Dummy2 WL).

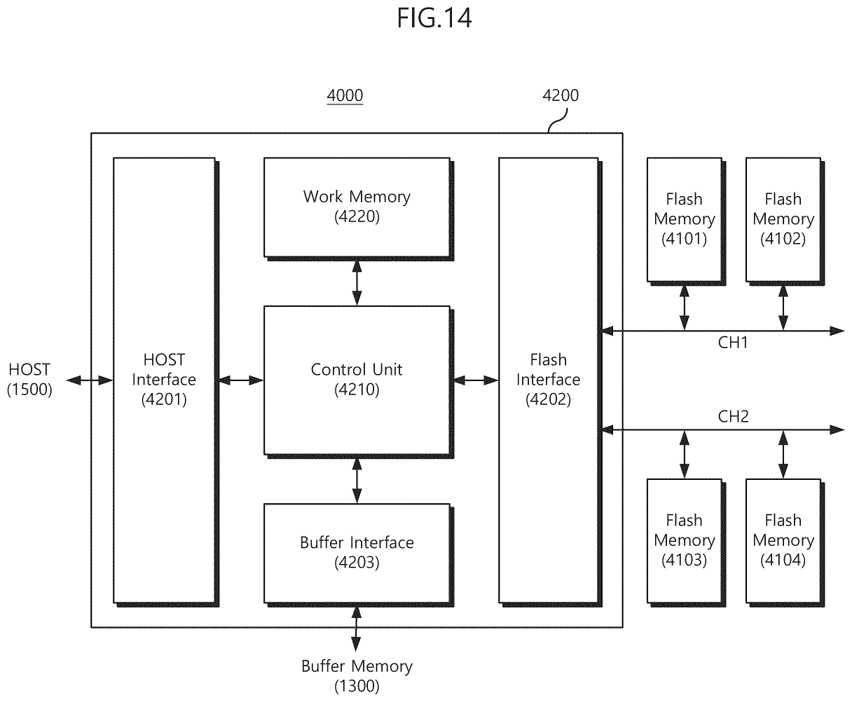

FIG. 14 is a block diagram illustrating an example in which a storage device is implemented with a solid state drive (SSD) according to some implementations. In FIG. 14, an SSD 4000 may include a plurality of flash memories 4101 to 4104 and an SSD controller 4200.

The first and second flash memories 4101 and 4102 may be connected with the SSD controller 4200 through a first channel CH1. The third and fourth flash memories 4103 and 4104 may be connected with the SSD controller 4200 through a second channel CH2. The number of channels connected with the SSD controller 4200 may be 2 or more. The number of flash memories connected with one channel may be 2 or more.

The SSD controller 4200 may include a host interface 4201, a flash interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding flash memory or may read data from the corresponding flash memory.

The SSD controller 4200 may be connected with the plurality of flash memories 4101 to 4104 through the flash interface 4202 and may be connected with a buffer memory 1300 through the buffer interface 4203. The flash interface 4202 may provide data, which are temporarily stored in the buffer memory 1300, to the flash memories through the channels CH1 and CH2. The flash interface 4202 may transfer the data read from the flash memories 4101 to 4104 to the buffer memory 1300.

The control unit 4210 may analyze and process the signal received from the host 1500. The control unit 4210 may control the host 1500 or the flash memories 4101 to 4104 through the host interface 4201 or the flash interface 4202. The control unit 4210 may control operations of the flash memories 4101 to 4104 by using firmware for driving the SSD 4000.

The SSD controller 4200 may manage data to be stored in the flash memories 4101 to 4104. In the sudden power-off event, the SSD controller 4200 may back the data stored in the work memory 4220 or the buffer memory 1300 up to the flash memories 4101 to 4104.

In some implementations, a detection may be made for whether a bridge exists between two word lines by changing a selected word line among the two word lines.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array connected to a first word line and a second word line;
an address decoder configured to select the first word line or the second word line; and
a word line bridge detector configured to detect whether a word line bridge exists between the first word line and the second word line,
wherein the word line bridge detector is configured to, during a word line precharge operation, precharge the first word line by connecting the first word line to a detection node, the word line bridge detector being configured to change a selected word line from the first word line to the second word line, and
wherein the word line bridge detector is configured to, during a word line develop operation, connect the second word line to the detection node, the word line bridge detector being configured to detect whether a word line bridge exists between the first word line and the second word line by detecting a change in a voltage level of the detection node.

2. The memory device of claim 1, wherein the word line bridge detector is configured to place the first word line in a floating state during the word line develop operation.

3. The memory device of claim 1, wherein the word line bridge detector is configured to compare the voltage level of the detection node with a reference voltage and detect whether the word line bridge exists between the first word line and the second word line.

4. The memory device of claim 1, wherein the word line bridge detector is configured to, based on the voltage level of the detection node maintaining higher than a reference voltage during the word line develop operation, determine that the word line bridge exists between the first word line and the second word line.

5. The memory device of claim 1, wherein the first word line and the second word line are adjacent to each other.

6. The memory device of claim 1, wherein the memory cell array is configured to have a multi-stack structure.

7. The memory device of claim 1, wherein the word line bridge detector comprises:
a word line selector configured to select the first word line or the second word line during a word line bridge detection operation;
a voltage switch configured to provide a precharge voltage to the first word line during the word line precharge operation and detect a voltage level of the detection node during the word line develop operation; and
a comparator configured to compare the voltage level of the detection node and a reference voltage and generate a leakage detection signal as a result of the comparison.

8. The memory device of claim 7, wherein the word line detector further comprises a leakage monitor configured to receive the leakage detection signal from the comparator and generate the leakage monitor signal.

9. The memory device of claim 1, wherein the voltage level of the detection node is configured to, based on no word line bridge existing between the first word line and the second word line, be lower than a reference voltage during the word line precharge operation.

10. The memory device of claim 1, wherein the word line bridge detector is configured to, based on a word line bridge existing between the first word line and the second word line, maintain the voltage level of the detection node higher than a reference voltage during the word line precharge operation.

11. A word line bridge detector of a memory device, comprising:
a word line selector configured to select a first word line or a second word line during a word line bridge detection operation;
a voltage switch configured to provide a precharge voltage to the first word line during a word line precharge operation and detect a voltage level of a detection node during a word line develop operation;
a comparator configured to compare the voltage level of the detection node and a reference voltage and generate a leakage detection signal as a result of the comparison; and
a leakage monitor configured to receive the leakage detection signal from the comparator and generate a leakage monitor signal,
wherein the word line selector is configured to, during a word line precharge operation, precharge the first word line by connecting the first word line to a detection node, the word line selector being configured to change a selected word line from the first word line to the second word line, and
wherein the word line selector is configured to, during a word line develop operation, connect the second word line to the detection node, the word line selector being configured to detect whether a word line bridge exists between the first word line and the second word line by detecting a change in the voltage level of the detection node.

12. The word line bridge detector of claim 11, wherein the word line selector is configured to place the first word line in a floating state during the word line develop operation.

13. The word line bridge detector of claim 11, wherein the comparator is configured to, based on the voltage level of the detection node maintaining higher than the reference voltage during the word line develop operation, determine that the word line bridge exists between the first word line and the second word line.

14. The word line bridge detector of claim 11, wherein the comparator is configured to, based on the voltage level of the detection node becoming lower than the reference voltage during the word line develop operation, determine that the word line bridge does not exist between the first word line and the second word line.

15. The word line bridge detector of claim 11, wherein the memory device comprises a flash memory.

16. A word line bridge detection method of a memory device, the method comprising:
providing the memory device including:
a memory cell array connected to a first word line and a second word line,
an address decoder configured to select the first word line or the second word line, and
a word line bridge detector configured to detect whether a word line bridge exists between the first word line and the second word line;
precharging, during a word line precharge operation, the first word line by connecting the first word line to a detection node;
changing a selected word line from the first word line to the second word line;
connecting, during a word line develop operation, the second word line to the detection node; and
detecting whether a word line bridge exists between the first word line and the second word line through a change in a voltage level of the detection node.

17. The word line bridge detection method of claim 16, wherein the first word line is configured to be in a floating state during the word line develop operation.

18. The word line bridge detection method of claim 16, wherein the word line bridge detector is configured to, based on the voltage level of the detection node maintaining higher than a reference voltage during the word line develop operation, determine that the word line bridge exists between the first word line and the second word line.

19. The word line bridge detection method of claim 16, wherein the word line bridge detector is configured to, based on the voltage level of the detection node becomes lower than a reference voltage during the word line develop operation, determine that the word line bridge does not exist between the first word line and the second word line.

20. The word line bridge detection method of claim 16, wherein a word line bridge detection operation is performed in a test mode of the memory device.
